(19) United States
(12) Patent Application Publication
(10) Pub. No.: US 2012/0094498 A1
(43) Pub. Date: Apr. 19, 2012

(54) METHOD FOR REDUCING PUNCH-THROUGH DEFECTS

(75) Inventors: Abhishek Dube, Hopewell Junction, NY (US); Eric Chad Toppin Harley, Hopewell Junction, NY (US); Richard John Murphy, Hopewell Junction, NY (US)

(73) Assignee: International Business Machines Corporation, Armonk, NY (US)

(21) Appl. No.: 12/904,294

(22) Filed: Oct. 14, 2010

(51) Int. Cl. H01L 21/306

(52) U.S. Cl. 438/706; 257/E21.215

(57) ABSTRACT

A method for reducing punch-through defects during semiconductor fabrication is disclosed. Various parameters such as partial pressure, total pressure, and temperature are manipulated to reduce punch-through defects, while still maintaining an acceptable etch rate. Some embodiments of the present invention also comprise the use of precursors, such as germane, to achieve faster etch rates with lower etch temperatures.

### FIELD OF THE INVENTION

The present invention relates generally to semiconductor fabrication, and more particularly to a method for reducing defects during etching.

### BACKGROUND OF THE INVENTION

Silicon Germanium (SiGe) epitaxial layers are used in semiconductor fabrication for various uses, such as formation of field effect transistor (FET) devices. The ever-increasing demand of new electronic systems such as telecommunication devices continues to place greater and greater demands on semiconductor devices. SiGe can be used with strained-Si channels, which, as will be appreciated by those skilled in the art, facilitates the excellent performance of CMOS type circuits. Unfortunately, the industry has encountered significant yield problems in the formation of epitaxial layers of SiGe over a silicon substrate or wafer surface. Therefore, it is desirable to have a method for reducing defects during semiconductor fabrication.

### SUMMARY

In one embodiment of the present invention, a method is provided for etching a silicon region on a semiconductor substrate. The method includes adding an etchant to a carrier gas, thereby creating an etchant gas mixture having an etchant partial pressure, and an etchant gas mixture total pressure, such that the etchant partial pressure is at least one order of magnitude less than the etchant gas mixture total pressure.

In another embodiment of the present invention, a method is provided for etching a silicon region on a semiconductor substrate. The method includes adding an etchant to a carrier gas, thereby creating an etchant gas mixture having an etchant partial pressure, and an etchant gas mixture total pressure, such that the etchant partial pressure has a value ranging from about 0.2 Torr to about 2.8 Torr. Further, precursor of hydrogen is added to the etchant gas mixture.

In another embodiment of the present invention, a method is provided for etching a silicon region on a semiconductor substrate. The method includes adding an HCl etchant to an H2 carrier gas, thereby creating an etchant gas mixture, such that the etchant partial pressure has a value ranging from about 0.2 Torr to about 2.8 Torr. Next, a GeH4 precursor is added to the etchant gas mixture. Then, an etch is performed at a temperature ranging from about 650 degrees Celsius to about 700 degrees Celsius.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG).

FIG. 1A shows a prior art semiconductor structure.

FIG. 1B shows a prior art semiconductor structure with a punch-through defect.

FIG. 2 shows a flowchart indicating process steps for embodiments of the present invention.

### DETAILED DESCRIPTION

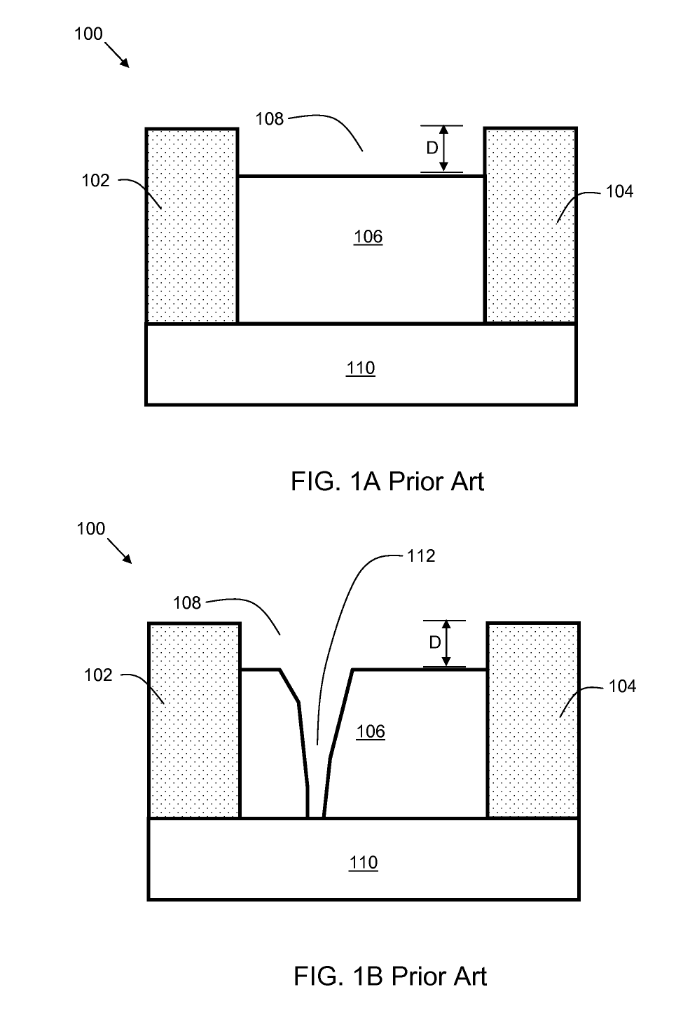

To aid in setting the context for embodiments of the present invention, a prior art structure is briefly described. FIG. 1A shows a prior art semiconductor structure 100. Structure 100 comprises two shallow trench isolation (STI) regions 102 and 104, disposed on an insulating layer 110. Layer 110 is typically an oxide layer. Disposed between STI regions 102 and 104 is silicon region 106. Silicon region 106 is also disposed on insulating layer 110. Typically, the structure is previously planarized such that regions 102, 104 and 106 are all of the same height. Then, a portion of the silicon region 106 is removed at its top, forming a recess 108 of depth D. Depending on the application and technology, depth D may be on the order of 3-20 nanometers. In many cases, an epitaxial layer (not shown) such as epitaxial silicon or silicon germanium (SiGe), is grown in the recess 108 to form an epitaxial layer. These epitaxial layers have various uses in improving semiconductor performance.

FIG. 1B shows a prior art semiconductor structure 100 with a punch-through defect 112. The punch-through defect 112 manifests as a crack or void in the silicon region 106 that may expose the insulating layer 110. The punch-through defect adversely affects any epitaxial layer that is subsequently grown above silicon region 106, since epitaxial layers will not grow properly over the area of the punch-through defect 112. The punch-through defects often occur as a result of the prior art recessing etch process, which can damage the silicon region 106. Therefore, it is desirable to have an improved method for performing a recess etch with a reduction in punch-through defects.

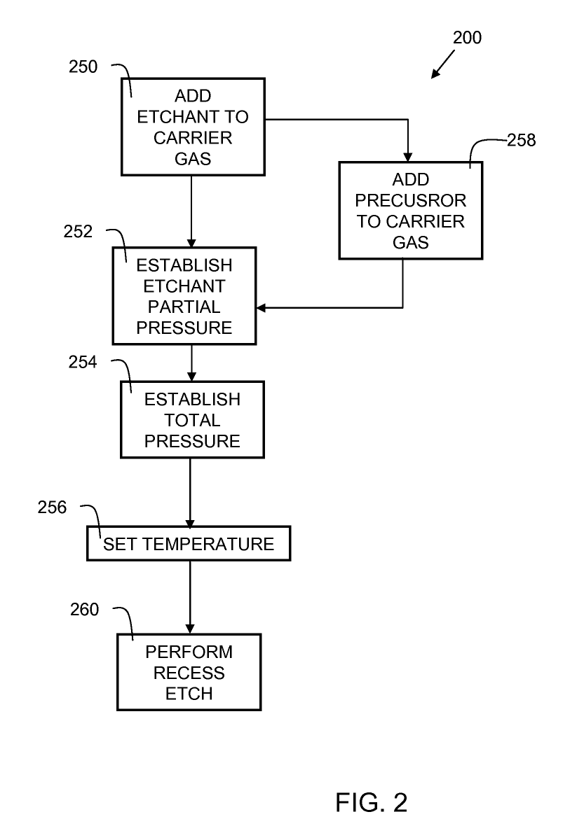

FIG. 2 shows a flowchart 200 indicating process steps for embodiments of the present invention. Process step 250 comprises adding an etchant gas to a carrier gas, which thereby creates an etchant gas mixture. The etchant gas mixture has a total pressure associated with it. The etchant, which is a constituent of the etchant gas mixture, has an etchant partial pressure associated with it, which is the pressure contribution of the etchant to the total pressure of the etchant gas mixture. In a preferred embodiment, the carrier gas is H2, and the etchant is HCl. In one embodiment, the flow rate of the H2 is in the range of 6 liters per minute to 8 liters per minute.

In process step 252, an etchant partial pressure is selected. The partial pressure is the amount of overall pressure due to a particular constituent. In prior art processes, the etchant partial pressure typically ranges from 150 Torr to 200 Torr (1 psi=51.715 Torr). In embodiments of the present invention, the etchant partial pressure is significantly lower, preferably in range of 0.1 Torr to 3 Torr. By lowering the etchant partial pressure significantly (two orders of magnitude lower than prior art methods), the number of punch-through defects is reduced. In one embodiment, the etchant partial pressure is at least one order of magnitude less than the total pressure.

While lowering the etchant partial pressure reduces punch-through defects, it also slows the etch rate, which may adversely affect production throughput. Therefore, a precursor is optionally added to the carrier gas in process step 258. In a preferred embodiment, the precursor is germane (GeH4). The germane increases the etch rate without adversely affecting the punch-through defect rate. In one embodiment, germane is introduced into the carrier gas at a flow rate of 40 to 400 sccm (standard cubic centimeters per minute). The addition of germane to HCl aids in reducing the punch-through defects as it induces the formation of H atoms, which in turn dissociate HCl into H2 gas and Cl atoms. The Cl atoms etch the silicon (106 of FIG. 1A) more uniformly than HCl by itself without the precursor. Hence, the GeH4 is not actually used as an etchant, but rather as a precursor to facilitate a faster etch rate and a more uniform etch, reducing undesirable etching effects such as facets and curved surfaces.

In process step 254, a total pressure value is established. The total pressure is the pressure of all the constituents. In prior art processes, the total pressure typically ranges from 500 Torr to 600 Torr (1 psi=51.715 Torr). In embodiments of the present invention, the total pressure is significantly lower (an order of magnitude lower), preferably in the range of 15 Torr to 60 Torr. By lowering the total pressure significantly, the differential etch rate between densely populated areas of silicon and sparsely populated areas of silicon is reduced. This is the so-called “loading effect” in which more silicon is etched from dense areas (such as SRAM structures) than from isolated silicon structures. It is desirable to minimize the loading effect to reduce process variability. Ideally, it is desirable to remove a consistent amount of material during an etch, regardless of the makeup of the structures undergoing the etch. However, in practice, the loading effect means that the etch rate is not the same amongst different structures on a semiconductor substrate that are undergoing the etch. However, by reducing the total pressure in accordance with embodiments of the present invention, the adverse loading effects are reduced.

In process step 256, a process temperature is established. In prior art processes, the process temperature typically ranges from 800 degrees Celsius to 900 degrees Celsius. In embodiments of the present invention, the process temperature is significantly lower, preferably in the range of 630 degrees Celsius to 720 degrees Celsius. By lowering the process temperature significantly, the diffusion of silicon is reduced, which reduces the risk of uncontrolled changes in the silicon morphology. Lowering the temperature has the effect of lowering the etch rate. However, this effect can be counteracted by the addition of the precursor, such as germane, as described in process step 258. The presence of the germane increases the etch rate, to counteract the effects of the lower temperature. Hence, with this embodiment of the present invention, the benefits of a lower temperature are achieved without significant compromising of the etch rate.

Alternate embodiments of the present invention may include, but are not limited to, use of an N2 (nitrogen), argon, or helium carrier gas, use of HBr or Cl2 as the etchant, and use of SiH4 or SiCl2H2 as etch stabilizing precursors by providing a Si source. If Cl2 is used as the etchant, then the carrier gas used is preferably N2, argon, or helium.

The embodiments of the present invention are novel methods of dry etching. They may be performed in an “epi” reactor just prior to an epitaxial process. In one embodiment, the etch process takes place in a CVD (chemical vapor deposition) reactor that also supports cSiGe deposition.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A method for etching a silicon region on a semiconductor substrate, comprising:
adding an etchant to a carrier gas, thereby creating an etchant gas mixture having an etchant partial pressure, and an etchant gas mixture total pressure, such that the etchant partial pressure is at least one order of magnitude less than the etchant gas mixture total pressure.

2. The method of claim 1, wherein the total pressure of the etchant gas mixture ranges from about 18 Torr to about 55 Torr, and wherein the etchant partial pressure has a value ranging from about 0.2 Torr to about 2.4 Torr.

3. The method of claim 1, wherein the step of adding an etchant comprises adding HCl.

4. The method of claim 1, wherein the step of adding an etchant comprises adding HBr.

5. The method of claim 1, wherein the step of adding an etchant comprises adding Cl2.

6. The method of claim 1, wherein the step of adding an etchant to a carrier gas comprises adding an etchant to a carrier gas comprised of H2.

7. The method of claim 1, wherein the step of adding an etchant to a carrier gas comprises adding an etchant to a carrier gas comprised of N2.

8. The method of claim 1, wherein the step of adding an etchant to a carrier gas comprises adding an etchant to a carrier gas comprised of argon.

9. The method of claim 1, wherein the step of adding an etchant to a carrier gas comprises adding an etchant to a carrier gas comprised of helium.

10. A method for etching a silicon region on a semiconductor substrate, comprising:
adding an etchant to a carrier gas, thereby creating an etchant gas mixture having an etchant partial pressure, and an etchant gas mixture total pressure, such that the etchant partial pressure has a value ranging from about 0.2 Torr to about 2.8 Torr; and
adding a precursor to the etchant gas mixture, wherein the precursor comprises a chemical substance which comprises hydrogen.

11. The method of claim 10, wherein the step of adding a precursor comprises adding GeH4.

12. The method of claim 10, wherein the step of adding a precursor comprises adding SiH4.

13. The method of claim 10, wherein the step of adding a precursor comprises adding SiCl2H2.

14. The method of claim 11, wherein the step of adding a precursor comprises adding a precursor to at a flow rate ranging from about 50 sccm to about 350 sccm.

15. The method of claim 10, wherein the step of adding an etchant to a carrier gas comprises adding an etchant to a carrier gas comprised of H2.

16. The method of claim 10, wherein the step or adding an etchant comprises adding HCl.

17. The method of claim 10, wherein the step of adding an etchant to a carrier gas comprises adding a Cl2 etchant to a carrier gas comprised of N2.

18. A method for etching a silicon region on a semiconductor substrate, comprising:
adding an HCl etchant to an H2 carrier gas, thereby creating an etchant gas mixture having an etchant partial pressure, and an etchant gas mixture total pressure, such that the etchant partial pressure has a value ranging from about 0.2 Torr to about 2.8 Torr;
adding a GeH4 precursor to the etchant gas mixture; and
performing an etch at a temperature ranging from about 650 degrees Celsius to about 700 degrees Celsius.

19. The method of claim 18, wherein the total pressure of the etchant gas mixture ranges from about 18 Torr to about 55 Torr.

20. The method of claim 19, further comprising:
establishing a flow rate of the H2 carrier gas in a range from about 6.2 liters per minute to about 7.8 liters per minute; and
establishing a flow rate of GeH4 in a range from about 45 sccm to about 375 sccm.
